(19) United States
(12) Patent Application Publication
(10) Pub. No.: US 2025/0240992 A1
(43) Pub. Date: Jul. 24, 2025

(54) SEMICONDUCTOR DEVICE, AND METHOD OF MANUFACTURING SEMICONDUCTOR DEVICE

(71) Applicant: Mitsubishi Electric Corporation, Tokyo (JP)

(72) Inventors: Hidenori FUJII, Tokyo (JP); Shinya SONEDA, Tokyo (JP); Yukio MATSUSHITA, Tokyo (JP)

(73) Assignee: Mitsubishi Electric Corporation, Tokyo (JP)

(21) Appl. No.: 18/917,128

(22) Filed: Oct. 16, 2024

(30) Foreign Application Priority Data
Jan. 18, 2024 (JP) 2024-005950

(51) Int. Cl. H01L 29/739; H01L 27/07; H01L 29/06; H01L 29/10; H01L 29/66

(52) U.S. Cl. CPC H10D 12/481; H10D 12/038; H10D 62/107; H10D 62/124; H10D 62/314; H10D 84/811

(57) ABSTRACT

A semiconductor device includes a source layer of a first conductivity type located in a surface portion of a semiconductor layer and defined by a concentration profile of a first impurity, a base layer of a second conductivity type located on a lower side of the source layer and defined by a concentration profile of a second impurity, a carrier stored layer of the first conductivity type located on a lower side of the base layer and defined by a concentration profile of a third impurity, a drift layer of the first conductivity type located on a lower side of the carrier stored layer, and a CSC layer of the second conductivity type defined by a concentration profile of a fourth impurity. A region containing the fourth impurity includes a region where a region containing the second impurity and a region containing the third impurity overlap each other.

### BACKGROUND OF THE INVENTION

### Field of the Invention

The present disclosure relates to a semiconductor device and a method of manufacturing a semiconductor device.

### Description of the Background Art

For example, Japanese Patent Application Laid-Open No. 2008-205015 discloses a technique of designing each of a p-type base layer and an n-type carrier stored layer of an IGBT to have a peak of impurity concentration in order to reduce variation in threshold voltage (Vth) of the IGBT.

In the IGBT of Japanese Patent Application Laid-Open No. 2008-205015, impurity peak concentration of the p-type base layer and the n-type carrier stored layer is stabilized, and thus, steady variation in threshold voltage is reduced. However, variation in depth and concentration occurs in a junction between an n⁺-type source layer and a p-type base layer and a junction between the p-type base layer and the n-type carrier stored layer. In this case, in a transient state of switching, current cannot be cut off at a place where impurity concentration is low and breakdown tolerance is lowered, or current concentration occurs due to local carrier distribution variation and breakdown tolerance is lowered. As a result, a reverse bias safe operating area (RBSOA) of the semiconductor device decreases.

### SUMMARY

An object of the present disclosure is to suppress variation in junction depth and concentration between a base layer and a carrier stored layer of a semiconductor device.

A semiconductor device according to the present disclosure includes a source layer, a base layer, a carrier stored layer, a drift layer, and a CSC layer formed in a semiconductor layer. The source layer is located in a surface portion of the semiconductor layer and is a region of a first conductivity type defined by a concentration profile of a first impurity. The base layer is located on a lower side of the source layer and is a region of a second conductivity type defined by a concentration profile of a second impurity. The carrier stored layer is a region of the first conductivity type that is located on a lower side of the base layer and defined by a concentration profile of a third impurity. The drift layer is a region of the first conductivity type located on a lower side of the carrier stored layer. The CSC layer is defined by a concentration profile of a fourth impurity, and is a region of the second conductivity type located such that a region containing the fourth impurity includes a region in which a region containing the second impurity of the base layer and a region containing the third impurity of the carrier stored layer overlap each other.

According to the present disclosure, by providing the CSC layer in the semiconductor device, it is possible to suppress variation in junction depth and concentration between the base layer and the carrier stored layer of the semiconductor device.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a diagram illustrating a configuration of a semiconductor device according to a first preferred embodiment;

FIG. 2 is a graph showing an impurity concentration profile of an n⁺-type source layer, a p-type base layer, an n-type carrier stored layer, an n⁻-type drift layer, and a p-type CSC layer of the semiconductor device according to the first preferred embodiment;

FIG. 3 is a flowchart for explaining a method of manufacturing the semiconductor device according to the first preferred embodiment;

FIG. 4 is a graph showing an impurity concentration profile of the n⁺-type source layer, the p-type base layer, the n-type carrier stored layer, the n⁻-type drift layer, and the p-type CSC layer of the semiconductor device according to a second preferred embodiment;

FIG. 5 is a graph showing an impurity concentration profile of the n⁺-type source layer, the p-type base layer, the n-type carrier stored layer, the n⁻-type drift layer, and the p-type CSC layer of the semiconductor device according to a third preferred embodiment;

FIG. 6 is a graph showing an impurity concentration profile of the n⁺-type source layer, the p-type base layer, the n-type carrier stored layer, the n⁻-type drift layer, and the p-type CSC layer of the semiconductor device according to a fourth preferred embodiment;

FIG. 7 is a graph showing an impurity concentration profile of the n⁺-type source layer, the p-type base layer, the n-type carrier stored layer, the n⁻-type drift layer, and the p-type CSC layer of the semiconductor device according to a fifth preferred embodiment;

FIG. 8 is a graph showing an impurity concentration profile of the n⁺-type source layer, the p-type base layer, the n-type carrier stored layer, the n⁻-type drift layer, and the p-type CSC layer of the semiconductor device according to a sixth preferred embodiment;

FIG. 9 is a diagram illustrating a configuration of the semiconductor device according to a seventh preferred embodiment;

FIG. 10 is a diagram illustrating a configuration of the semiconductor device according to an eighth preferred embodiment; and

FIG. 11 is a diagram illustrating a configuration of the semiconductor device according to a ninth preferred embodiment.

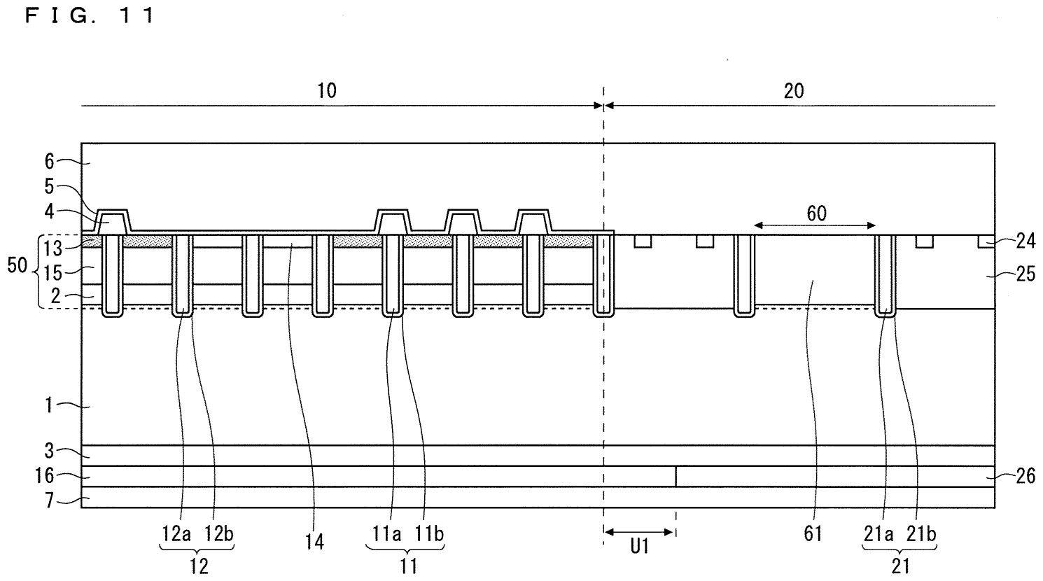

### DESCRIPTION OF THE PREFERRED EMBODIMENTS

In description below, n and p represent a conductivity type of a semiconductor, and in the present disclosure, a first conductivity type is described as an n type and a second conductivity type is described as a p type, but conversely, the first conductivity type may be described as a p type and the second conductivity type may be described as an n type. Further, n⁻ indicates that impurity concentration is lower than that of n, and n⁺ indicates that impurity concentration is higher than that of n. Similarly, p⁻ indicates that impurity concentration is lower than that of p, and p⁺ indicates that impurity concentration is higher than that of p.

Further, degree of impurity concentration of each region is defined by peak

concentration. That is, a region having high (or low) impurity concentration means a region having high (or low) impurity peak concentration.

### First Preferred Embodiment

Hereinafter, a configuration of a semiconductor device according to a first preferred embodiment will be described. A MOSFET (Metal Oxide Semiconductor Field

Effect Transistor), an IGBT (Insulated Gate Bipolar Transistor), an RC-IGBT (Reverse Conducting IGBT), an SBD (Schottky Barrier Diode), a PN diode, and the like are assumed as a semiconductor element included in the semiconductor device, but here, the semiconductor element is assumed to be an RC-IGBT.

A material of the semiconductor element may be silicon (Si) or a wide band gap semiconductor such as silicon carbide (SiC). A semiconductor device formed using a wide band gap semiconductor is excellent in operation at high voltage, large current, and high temperature as compared with a semiconductor device using silicon. Examples of the wide bandgap semiconductor include a gallium nitride (GaN)-based material and diamond in addition to silicon carbide.

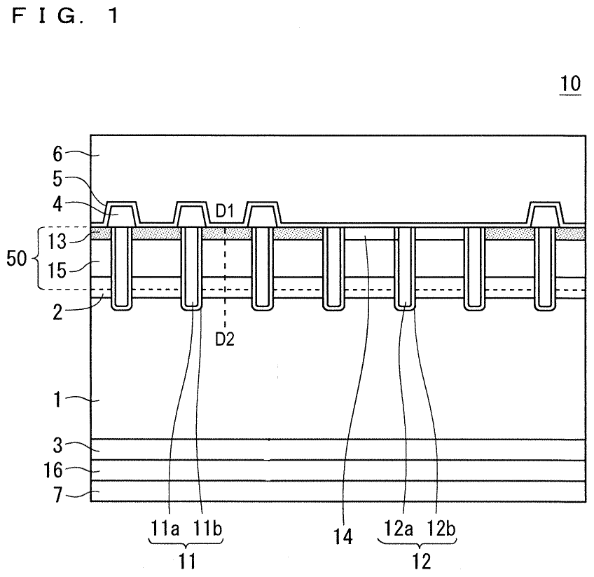

FIG. 1 is a diagram illustrating a configuration of the semiconductor device according to the first preferred embodiment, and is a cross-sectional view of an IGBT region 10 functioning as an IGBT in an RC-IGBT. Note that a diode region functioning as a diode in an RC-IGBT will be described in a preferred embodiment described later.

As illustrated in FIG. 1, an active trench gate 11 and a dummy trench gate 12 are provided in the IGBT region 10. The active trench gate 11 is configured such that a gate trench electrode 11a is provided via a gate trench insulating film 11b in a trench formed in a semiconductor substrate (semiconductor layer). The dummy trench gate 12 is configured by providing a dummy trench electrode 12a via a dummy trench insulating film 12b in a trench formed in a semiconductor substrate. The gate trench electrode 11a of the active trench gate 11 is electrically connected to a gate pad (not illustrated). The dummy trench electrode 12a of the dummy trench gate 12 is electrically connected to an emitter electrode 6.

On both sides in a width direction of the active trench gate 11, an n⁺-type source layer 13 is provided in contact with the gate trench insulating film 11b. The n⁺-type source layer 13 is a semiconductor layer containing, for example, arsenic (As), phosphorus (P), or the like as an n-type impurity. That is, the n⁺-type source layer 13 is located in a surface portion of the semiconductor layer, and is defined by a concentration profile of an n-type first impurity. Concentration of an n-type impurity in the n⁺-type source layer 13 is, for example, 1.0E+17/cm³ to 1.0E+20/cm³.

A p⁺-type contact layer 14 is provided between two adjacent ones of the dummy trench gates 12. Further, the n⁺-type source layer 13 may be provided alternately with the p⁺-type contact layer 14 along an extending direction of the active trench gate 11. The p⁺-type contact layer 14 is a semiconductor layer containing, for example, boron (B), aluminum (Al), or the like as a p-type impurity. Concentration of a p-type impurity of the p⁺-type contact layer 14 is, for example, 1.0E+15/cm³ to 1.0E+20/cm³.

In the example of FIG. 1, a set of three of the active trench gates 11 and a set of three of the dummy trench gates 12 are alternately arranged. However, the number of the active trench gates 11 included in one set of the active trench gates 11 and the number of the dummy trench gates 12 included in one set of the dummy trench gates 12 are not limited.

The number of the dummy trench gates 12 may be zero. That is, all trenches provided in the IGBT region 10 may be used as the active trench gate 11.

The semiconductor device includes an n⁻-type drift layer 1 including a semiconductor substrate. The n⁻-type drift layer 1 is a semiconductor layer containing, for example, arsenic or phosphorus as an n-type impurity. Concentration of an n-type impurity in the n⁻-type drift layer 1 is 1.0E+12/cm³ to 1.0E+15/cm³. A semiconductor substrate is in a range from the n⁺-type source layer 13 and the p⁺-type contact layer 14 to a p-type collector layer 16 illustrated in FIG. 1. In FIG. 1, an upper end in the diagram of the n⁺-type source layer 13 and the p⁺-type contact layer 14 is referred to as a first main surface of the semiconductor substrate, and a lower end in the diagram of the p-type collector layer 16 is referred to as a second main surface of the semiconductor substrate. The first main surface of the semiconductor substrate is a main surface on the front surface side of the semiconductor device, and the second main surface of the semiconductor substrate is a main surface on the back surface side of the semiconductor device. The semiconductor device includes the n⁻-type drift layer 1 between the first main surface and the second main surface facing the first main surface in the IGBT region 10 that is a cell region. Hereinafter, the first main surface side of the semiconductor substrate may be referred to as an “upper side”, and the second main surface side may be referred to as a “lower side”.

A p-type base layer 15 is provided on the second main surface side of the n⁺-type source layer 13 and the p⁺-type contact layer 14. The p-type base layer 15 is a semiconductor layer containing, for example, boron or aluminum as a p-type impurity. That is, the p-type base layer 15 is located on the lower side of the n⁺-type source layer 13, and is defined by a concentration profile of a p-type second impurity. Concentration of a p-type impurity of the p-type base layer 15 is 1.0E+12/cm³ to 1.0E+19/cm³. The p-type base layer 15 is in contact with the gate trench insulating film 11b of the active trench gate 11.

On the first main surface side of the p-type base layer 15, the n⁺-type source layer 13 is provided in contact with the gate trench insulating film 11b of the active trench gate 11, and the p⁺-type contact layer 14 is provided in a remaining region. The n⁺-type source layer 13 and the p⁺-type contact layer 14 constitute the first main surface of the semiconductor substrate. Note that the p⁺-type contact layer 14 is a region having higher p-type impurity concentration than the p-type base layer 15.

On the second main surface side of the p-type base layer 15, an n-type carrier stored layer 2 having higher concentration of an n-type impurity than the n⁻-type drift layer 1 is provided. The n-type carrier stored layer 2 is a semiconductor layer containing, for example, arsenic or phosphorus as an n-type impurity. That is, the n-type carrier stored layer 2 is located on the lower side of the p-type base layer 15, and is defined by a concentration profile of an n-type third impurity. Concentration of an n-type impurity of the n-type carrier stored layer 2 is, for example, 1.0E+13/cm³ to 1.0E+17/cm³. By providing the n-type carrier stored layer 2, an energization loss when current flows in the IGBT region 10 can be reduced.

The n⁻-type drift layer 1 is located on the second main surface side of the n type carrier stored layer 2. Further, an n-type buffer layer 3 having higher concentration of an n-type impurity than the n⁻-type drift layer 1 is provided on the second main surface side of the n⁻-type drift layer 1. The n-type buffer layer 3 is provided to prevent punch-through of a depletion layer extending from the p-type base layer 15 to the second main surface side when the semiconductor device is in an off state. The n-type buffer layer 3 may be formed by, for example, injecting phosphorus (P) or a proton (H+), or may be formed by injecting both phosphorus (P) and a proton (H+). Concentration of an n-type impurity in the n-type buffer layer 3 is, for example, 1.0E+12/cm³ to 1.0E+18/cm³.

Note that the n⁻-type drift layer 1 may also be provided in a region of the n-type buffer layer 3 illustrated in FIG. 1 without provision of the n-type buffer layer 3. The n-type buffer layer 3 and the n⁻-type drift layer 1 may be collectively referred to as a drift layer.

The p-type collector layer 16 is provided on the second main surface side of the n-type buffer layer 3. That is, the p-type collector layer 16 is provided between the n⁻-type drift layer 1 and the second main surface. The p-type collector layer 16 is a semiconductor layer containing, for example, boron or aluminum as a p-type impurity. Concentration of a p-type impurity in the p-type collector layer 16 is, for example, 1.0E+16/cm³ to 1.0E+20/cm³. The p-type collector layer 16 constitutes the second main surface of the semiconductor substrate.

As illustrated in FIG. 1, the active trench gate 11 and the dummy trench gate 12 penetrate the p-type base layer 15 and the n-type carrier stored layer 2 from the first main surface of the semiconductor substrate and reach the n⁻-type drift layer 1. The gate trench electrode 11a of the active trench gate 11 faces the n⁺-type source layer 13, the p-type base layer 15, the n-type carrier stored layer 2, and the n⁻-type drift layer 1 via the gate trench insulating film 11b. When gate drive voltage is applied to the gate trench electrode 11a, a channel is formed in the p-type base layer 15 in contact with the gate trench insulating film 11b.

An interlayer insulating film 4 is provided on the gate trench electrode 11a of the active trench gate 11. Barrier metal 5 is formed on a region where the interlayer insulating film 4 is not provided on the first main surface of the semiconductor substrate and on the interlayer insulating film 4. The barrier metal 5 may be, for example, a conductor containing titanium (Ti), and may be, for example, titanium nitride or TiSi obtained by alloying titanium and silicon (Si). The barrier metal 5 is in ohmic contact with the n⁺-type source layer 13, the p⁺-type contact layer 14, and the dummy trench electrode 12a, and is electrically connected to the n⁺-type source layer 13, the p⁺-type contact layer 14, and the dummy trench electrode 12a. The emitter electrode 6 is provided on the barrier metal 5. The emitter electrode 6 may be formed of, for example, an aluminum alloy such as an aluminum silicon alloy (Al—Si-based alloy), or may be an electrode including a plurality of layers of metal films in which a plating film is formed on an electrode formed of an aluminum alloy by electroless plating or electrolytic plating. The plating film formed by electroless plating or electrolytic plating may be, for example, a nickel (Ni) plating film.

In a case where there is a fine region between adjacent ones of the interlayer insulating films 4 or the like and a region where favorable embedding cannot be obtained by the emitter electrode 6, tungsten having better embeddability than the emitter electrode 6 may be arranged in the fine region, and the emitter electrode 6 may be provided on the tungsten. The emitter electrode 6 may be provided on the n⁺-type source layer 13, the p⁺-type contact layer 14, and the dummy trench electrode 12a without provision of the barrier metal 5. Further, the barrier metal 5 may be provided only on an n-type semiconductor layer such as the n⁺-type source layer 13. The barrier metal 5 and the emitter electrode 6 may be collectively referred to as an emitter electrode.

Although FIG. 1 illustrates a diagram in which the interlayer insulating film 4 is not provided on the dummy trench electrode 12a of the dummy trench gate 12, the interlayer insulating film 4 may be formed on the dummy trench electrode 12a of the dummy trench gate 12. In a case where the interlayer insulating film 4 is formed on the dummy trench electrode 12a of the dummy trench gate 12, the emitter electrode 6 and the dummy trench electrode 12a only need to be electrically connected in another cross section.

A collector electrode 7 is provided on the second main surface side of the p-type collector layer 16. Similarly to the emitter electrode 6, the collector electrode 7 may include an aluminum alloy, or an aluminum alloy and a plating film. Further, the collector electrode 7 may have a configuration different from that of the emitter electrode 6. The collector electrode 7 is in ohmic contact with the p-type collector layer 16 and is electrically connected to the p-type collector layer 16.

In addition to the above configuration, the semiconductor device according to the first preferred embodiment includes a p-type carrier storage control (CSC) layer 50 so as to overlap the n⁺-type source layer 13, the p-type base layer 15, and the n-type carrier stored layer 2. The p-type CSC layer 50 is a semiconductor layer containing, for example, boron (B), aluminum (Al), or the like as a p-type impurity. That is, the p-type CSC layer 50 is defined by a concentration profile of a p-type fourth impurity. In the present preferred embodiment, boron is used as a p-type impurity constituting p-type base layer 15.

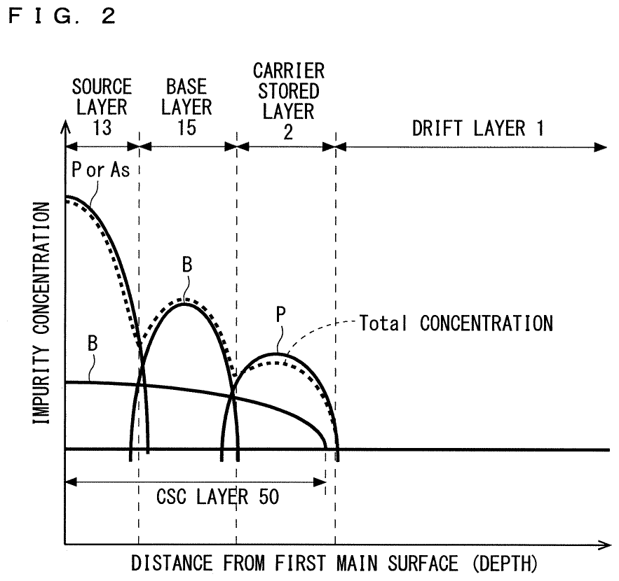

FIG. 2 shows an impurity concentration profile of the n⁺-type source layer 13, the p-type base layer 15, the n-type carrier stored layer 2, the n⁻-type drift layer 1, and the p-type CSC layer 50 in the semiconductor device according to the first preferred embodiment. FIG. 2 illustrates an impurity concentration profile in a depth direction from the first main surface of the semiconductor substrate in a portion along a broken line D1-D2 in FIG. 1.

As illustrated in FIG. 2, a concentration profile of a fourth impurity (B) defining the p-type CSC layer 50 has concentration distribution with a gentle gradient in a depth direction of a semiconductor substrate. Further, a position (depth) where the p-type CSC layer 50 is formed is set such that a region containing a fourth impurity that defines the p-type CSC layer 50 includes a region in which a region containing a second impurity (B) that defines the p-type base layer 15 and a region containing a third impurity (P) that defines the n-type carrier stored layer 2 overlap each other.

As described above, the p-type CSC layer 50 is formed so as to overlap a portion where the p-type base layer 15 and the n-type carrier stored layer 2 are joined, so that variation in depth and concentration of a junction between the p-type base layer 15 and the n-type carrier stored layer 2 is reduced. By the above, a decrease in an RBSOA of the semiconductor device is suppressed.

Further, as illustrated in FIG. 2, a region containing a fourth impurity that defines p-type CSC layer 50 may include a region in which a region containing a first impurity (P or As) that defines the n⁺-type source layer 13 overlaps a region containing a second impurity that defines the p-type base layer 15. In this case, variation in depth and concentration of a junction between the n⁺-type source layer 13 and the p-type base layer 15 is also reduced, and a decrease in an RBSOA of the semiconductor device is further suppressed.

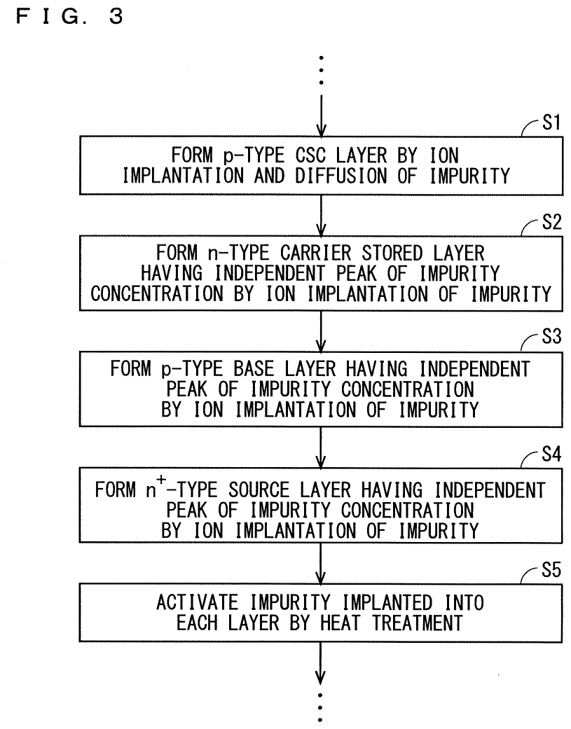

Here, a method of manufacturing the semiconductor device according to the first preferred embodiment will be described. The method of manufacturing the semiconductor device according to the first preferred embodiment may be the same as a method of manufacturing a general RC-IGBT except for a process of forming the n⁺-type source layer 13, the p-type base layer 15, the n-type carrier stored layer 2, and the p-type CSC layer 50. In view of the above, a process of forming the n⁺-type source layer 13, the p-type base layer 15, the n-type carrier stored layer 2, and the p-type CSC layer 50 will be described with reference to a flowchart of FIG. 3.

First, a p-type fourth impurity that defines the p-type CSC layer 50 is ion-implanted from the first main surface side of the n⁻-type drift layer 1 on which the n⁻-type drift layer 1 is formed, and a fourth impurity is diffused into the semiconductor substrate by heat treatment to form the p-type CSC layer 50 (Step S1). By diffusing a fourth impurity, the p-type CSC layer 50 having concentration distribution with a gentle gradient in a depth direction of the semiconductor substrate can be formed.

Next, by ion-implanting an n-type first impurity that defines the n⁺-type source layer 13 into the semiconductor substrate from the first main surface side, the n⁺-type source layer 13 having an independent peak of impurity concentration is formed in a surface portion of the semiconductor substrate (Step S2). Subsequently, by ion-implanting a p-type second impurity that defines the p-type base layer 15 into the semiconductor substrate from the first main surface side, the p-type base layer 15 having an independent peak of impurity concentration is formed on the lower side of the n⁺-type source layer 13 (Step S3). Furthermore, by ion-implanting a third impurity into the semiconductor substrate from the first main surface side, the n-type carrier stored layer 2 of a first conductivity type having an independent peak of impurity concentration is formed on the lower side of the p-type base layer 15 (Step S4).

In the processes of Steps S2 to S4, the n⁺-type source layer 13, the p-type base layer 15, and the n-type carrier stored layer 2 are formed such that a junction portion between the n⁺-type source layer 13 and the p-type base layer 15 and a junction portion between the p-type base layer 15 and the n-type carrier stored layer 2 are included in the p-type CSC layer 50 formed in Step S1, and the order of execution of Steps S2, S3, and S4 is not limited.

After the above, heat treatment for activating an impurity implanted into each of the n⁺-type source layer 13, the p-type base layer 15, the n-type carrier stored layer 2, and the p-type CSC layer 50 is performed (Step S5).

By the above processes, the n⁺-type source layer 13, the p-type base layer 15, the n-type carrier stored layer 2, and the p-type CSC layer 50 of the semiconductor device according to the first preferred embodiment can be formed.

### Second Preferred Embodiment

A configuration of the semiconductor device according to a second preferred embodiment is basically similar to that of the first preferred embodiment (FIG. 1), but an impurity concentration profile of the p-type CSC layer 50 is different from that of the first preferred embodiment.

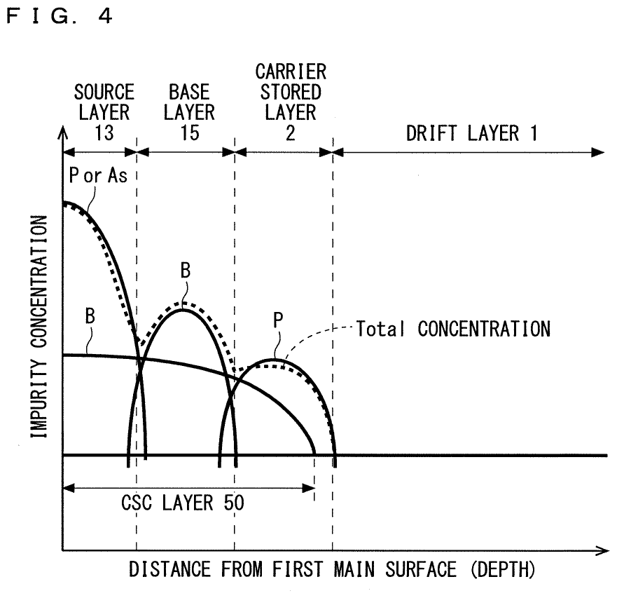

FIG. 4 shows an impurity concentration profile of the n⁺-type source layer 13, the p-type base layer 15, the n-type carrier stored layer 2, the n⁻-type drift layer 1, and the p-type CSC layer 50 in the semiconductor device according to the second preferred embodiment. As illustrated in FIG. 4, in the second preferred embodiment, in a region where a region containing a second impurity of the p-type base layer 15 and a region containing a third impurity of the n-type carrier stored layer 2 overlap each other, concentration of a fourth impurity in the p-type CSC layer 50 is higher than concentration of a second impurity and concentration of a third impurity.

According to the semiconductor device of the second preferred embodiment, since variation in depth of a junction between the p-type base layer 15 and the n-type carrier stored layer 2 is further reduced, a decrease in an RBSOA of the semiconductor device is further suppressed.

Note that the semiconductor device of the second preferred embodiment can be formed by changing conditions of ion implantation and heat treatment for forming the p-type CSC layer 50 in the method of manufacturing the semiconductor device according to the first preferred embodiment.

### Third Preferred Embodiment

A configuration of the semiconductor device according to a third preferred embodiment is also basically similar to that of the first preferred embodiment (FIG. 1), but an impurity concentration profile of the p-type CSC layer 50 is different from that of the first preferred embodiment.

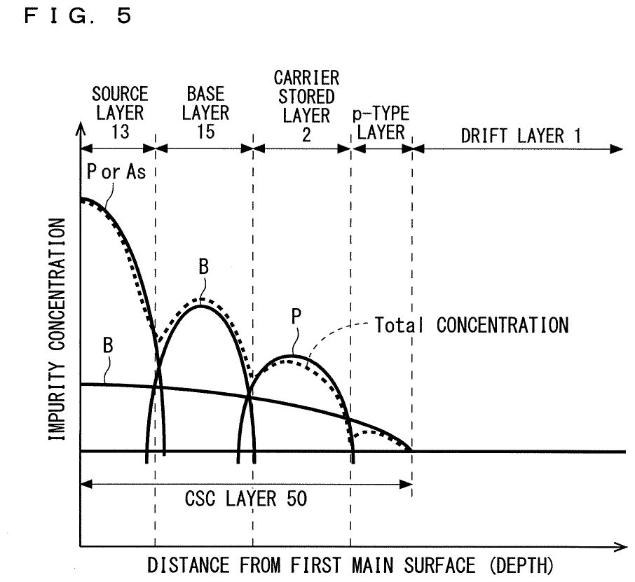

FIG. 5 shows an impurity concentration profile of the n⁺-type source layer 13, the p-type base layer 15, the n-type carrier stored layer 2, the n⁻-type drift layer 1, and the p-type CSC layer 50 in the semiconductor device according to the third preferred embodiment. As illustrated in FIG. 5, in the third preferred embodiment, a region containing a fourth impurity in the p-type CSC layer 50 reaches below a region containing a third impurity in the n-type carrier stored layer 2. For this reason, a p-type layer including the p-type CSC layer 50 is formed between the n-type carrier stored layer 2 and the n-type drift layer 1.

According to the semiconductor device of the third preferred embodiment, since the n-type carrier stored layer 2 and the n⁻-type drift layer 1 are separated by a p-type layer, local variation in carrier distribution is reduced, which can contribute to improvement in an

RBSOA of the semiconductor device.

The semiconductor device of the third preferred embodiment can also be formed by changing conditions of ion implantation and heat treatment for forming the p-type CSC layer 50 in the method of manufacturing the semiconductor device according to the first preferred embodiment.

### Fourth Preferred Embodiment

A configuration of the semiconductor device according to a fourth preferred embodiment is also basically similar to that of the first preferred embodiment (FIG. 1), but an impurity concentration profile of the p-type CSC layer 50 is different from that of the first preferred embodiment.

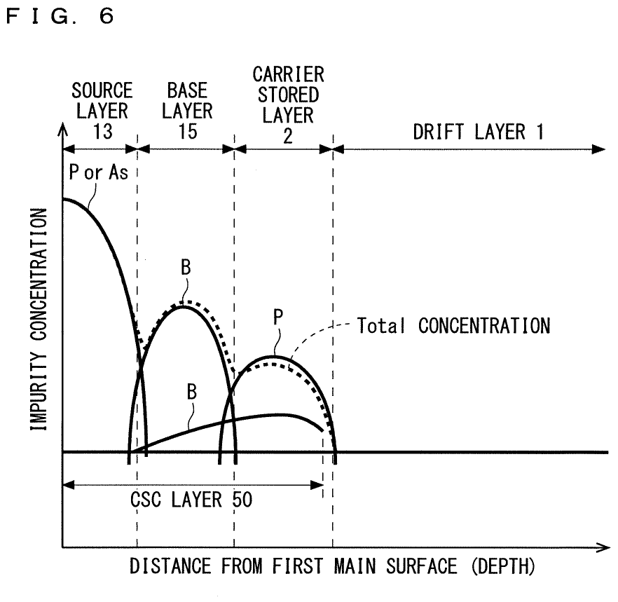

FIG. 6 shows an impurity concentration profile of the n⁺-type source layer 13, the p-type base layer 15, the n-type carrier stored layer 2, the n⁻-type drift layer 1, and the p-type CSC layer 50 in the semiconductor device according to the fourth preferred embodiment. As illustrated in FIG. 6, in the fourth preferred embodiment, a position of a concentration peak of a fourth impurity in the p-type CSC layer 50 is located below a position of a concentration peak of a third impurity in the n-type carrier stored layer 2.

According to the semiconductor device according to the fourth preferred embodiment, variation in gradient of impurity concentration in a junction portion between the n-type carrier stored layer 2 and the n⁻-type drift layer 1 is reduced, so that an effect of reducing variation in saturation voltage (Vsat) (on-voltage) of the semiconductor device can be expected.

The semiconductor device of the fourth preferred embodiment can also be formed by changing conditions of ion implantation and heat treatment for forming the p-type CSC layer 50 in the method of manufacturing the semiconductor device according to the first preferred embodiment.

### Fifth Preferred Embodiment

A configuration of the semiconductor device according to a fifth preferred embodiment is also basically similar to that of the first preferred embodiment (FIG. 1), but an impurity concentration profile of the p-type CSC layer 50 is different from that of the first preferred embodiment.

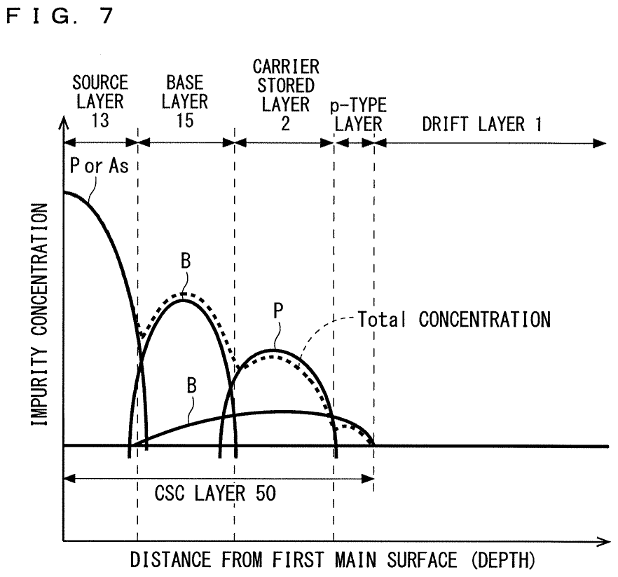

FIG. 7 shows an impurity concentration profile of the n⁺-type source layer 13, the p-type base layer 15, the n-type carrier stored layer 2, the n⁻-type drift layer 1, and the p-type CSC layer 50 in the semiconductor device according to the fifth preferred embodiment. Similarly to the fourth preferred embodiment, a position of a concentration peak of a fourth impurity in the p-type CSC layer 50 is located below a position of a concentration peak of a third impurity in the n-type carrier stored layer 2. As illustrated in FIG. 7, in the fifth preferred embodiment, a tail portion (bottom portion) in a concentration profile of a fourth impurity in the p-type CSC layer 50 reaches below a region containing a third impurity in the n-type carrier stored layer 2.

According to the semiconductor device according to the fifth preferred embodiment, both an effect of the third preferred embodiment and an effect of the fourth preferred embodiment can be obtained. That is, both effects of improving an RBSOA of the semiconductor device and reducing variation in saturation voltage can be obtained.

The semiconductor device of the fifth preferred embodiment can also be formed by changing conditions of ion implantation and heat treatment for forming the p-type CSC layer 50 in the method of manufacturing the semiconductor device according to the first preferred embodiment.

### Sixth Preferred Embodiment

A configuration of the semiconductor device according to a sixth preferred embodiment is also basically similar to that of the first preferred embodiment (FIG. 1), but an impurity concentration profile of the p-type CSC layer 50 is different from that of the first preferred embodiment.

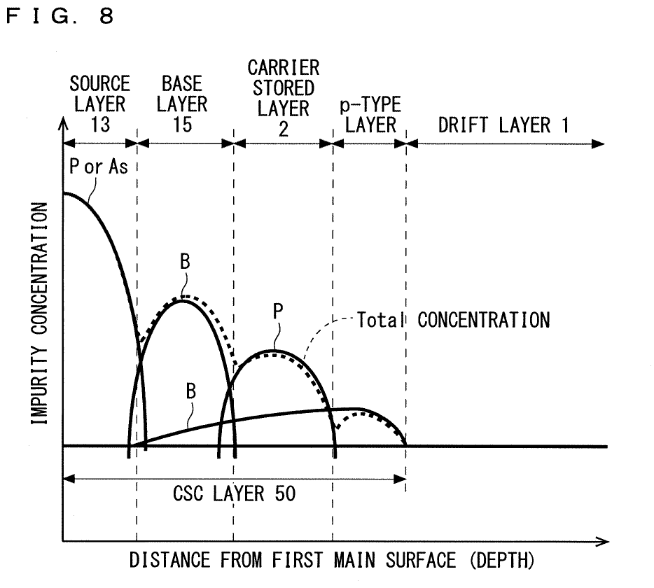

FIG. 8 shows an impurity concentration profile of the n⁺-type source layer 13, the p-type base layer 15, the n-type carrier stored layer 2, the n⁻-type drift layer 1, and the p-type CSC layer 50 in the semiconductor device according to the sixth preferred embodiment. As illustrated in FIG. 8, in the sixth preferred embodiment, a position of a concentration peak of a fourth impurity in the p-type CSC layer 50 is located below a region containing a third impurity in the n-type carrier stored layer 2.

Also in the semiconductor device according to the sixth preferred embodiment, both an effect of the third preferred embodiment and an effect of the fourth preferred embodiment can be obtained. Further, since peak concentration distribution of a fourth impurity in the p-type CSC layer 50 is constant as compared with the sixth preferred embodiment, it is possible to further contribute to both improvement of an RBSOA of the semiconductor device and reduction of variation in saturation voltage.

The semiconductor device of the sixth preferred embodiment can also be formed by changing conditions of ion implantation and heat treatment for forming the p-type CSC layer 50 in the method of manufacturing the semiconductor device according to the first preferred embodiment.

### Seventh Preferred Embodiment

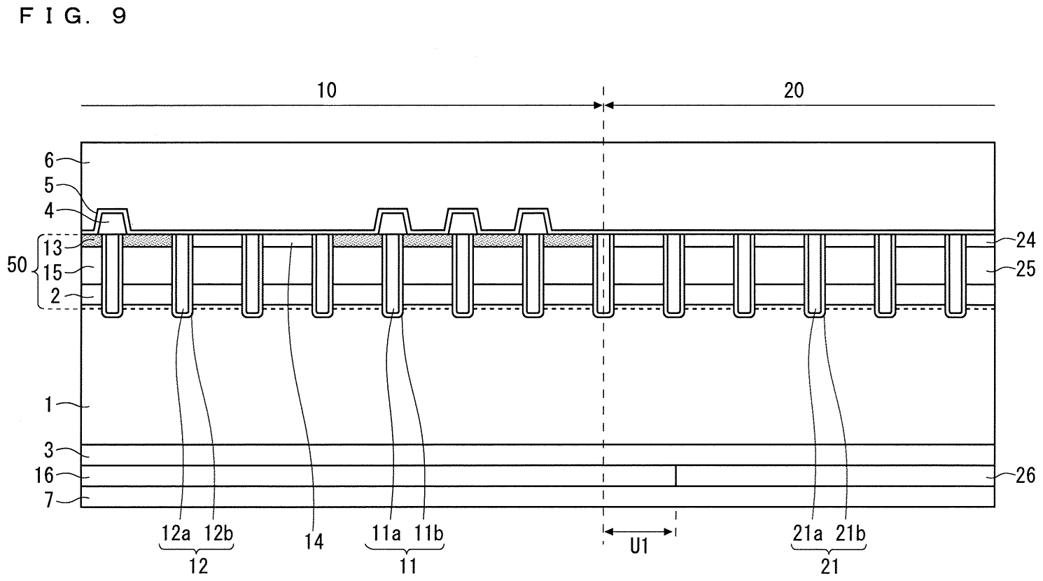

FIG. 9 is a diagram illustrating a configuration of the semiconductor device according to a seventh preferred embodiment, and is a cross-sectional view of the IGBT region 10 and a diode region 20 of an RC-IGBT. A configuration of the IGBT region 10 of the semiconductor device according to the seventh preferred embodiment is similar to that of the third preferred embodiment. That is, a region containing a fourth impurity in the p-type CSC layer 50 reaches below a region containing a third impurity in the n-type carrier stored layer 2. For this reason, a p-type layer including the p-type CSC layer 50 is formed between the n-type carrier stored layer 2 and the n⁻-type drift layer 1.

Next, the diode region 20 will be described. As illustrated in FIG. 9, a diode trench gate 21 is provided in the diode region 20. The diode trench gate 21 is configured by providing a diode trench electrode 21a in a trench formed in the semiconductor substrate of the diode region 20 via a diode trench insulating film 21b. The diode trench electrode 21a faces the n⁻-type drift layer 1 via the diode trench insulating film 21b. A p⁺-type contact layer 24 and a p-type anode layer 25 are provided between two adjacent ones of the diode trench gates 21.

The p⁺-type contact layer 24 and the p-type anode layer 25 are semiconductor layers containing, for example, boron or aluminum as a p-type impurity. Concentration of a p-type impurity of the p⁺-type contact layer 24 is, for example, 1.0E+15/cm³ to 1.0E+20/cm³. Concentration of a p-type impurity of the p-type anode layer 25 is set to be lower than that of the p⁺-type contact layer 24, and is, for example, 1.0E+12/cm³ to 1.0E+19/cm³. The p⁺-type contact layer 24 and the p-type anode layer 25 may be alternately provided along an extending direction of the diode trench gate 21.

The semiconductor device also includes the n⁻-type drift layer 1 including a semiconductor substrate in the diode region 20 as in the IGBT region 10. The n⁻-type drift layer 1 of the diode region 20 and the n⁻-type drift layer 1 of the IGBT region 10 are continuously and integrally formed, and are formed of the same semiconductor substrate. In FIG. 9, the semiconductor substrate is in a range from the p⁺-type contact layer 24 to an n⁺-type cathode layer 26. In FIG. 9, an upper end in the diagram of the p⁺-type contact layer 24 is referred to as the first main surface of the semiconductor substrate, and a lower end in the diagram of the n⁺-type cathode layer 26 is referred to as the second main surface of the semiconductor substrate. The first main surface of the diode region 20 and the first main surface of the IGBT region 10 are flush, and the second main surface of the diode region 20 and the second main surface of the IGBT region 10 are flush.

As illustrated in FIG. 9, also in the diode region 20, similarly to the IGBT region 10, the n-type carrier stored layer 2 is provided on the first main surface side of the n⁻-type drift layer 1, and the n-type buffer layer 3 is provided on the second main surface side of the n⁻-type drift layer 1. The n-type carrier stored layer 2 and the n-type buffer layer 3 provided in the diode region 20 have the same configuration as the n-type carrier stored layer 2 and the n-type buffer layer 3 provided in the IGBT region 10. Note that the n-type carrier stored layer 2 is not necessarily provided in the IGBT region 10 and the diode region 20. Further, similarly to the IGBT region 10, the n⁻-type drift layer 1, the n-type carrier stored layer 2, and the n-type buffer layer 3 may be collectively referred to as a drift layer.

The p-type anode layer 25 is provided on the first main surface side of the n-type carrier stored layer 2. The p-type anode layer 25 is provided between the n⁻-type drift layer 1 and the first main surface. The p-type anode layer 25 may have the same concentration of a p-type impurity as the p-type base layer 15 of the IGBT region 10, so that the p-type anode layer 25 and the p-type base layer 15 are formed at the same time (that is, in the same process). Further, concentration of a p-type impurity of the p-type anode layer 25 may be set to be lower than concentration of a p-type impurity of the p-type base layer 15 of the IGBT region 10 so as to reduce an amount of holes injected into the diode region 20 during diode operation. By reducing an amount of holes injected during diode operation, a recovery loss during diode operation can be reduced.

In the present preferred embodiment, the p-type anode layer 25 and the p-type base layer 15 are simultaneously formed. Therefore, the p-type anode layer 25 is located in a surface portion of a semiconductor layer and has the same impurity concentration profile as the p-type base layer 15. The “same” impurity concentration profiles do not need to be completely the same, and may be substantially the same.

The p⁺-type contact layer 24 is provided on the first main surface side of the p-type anode layer 25. Concentration of a p-type impurity of the p⁺-type contact layer 24 may be the same as or different from concentration of a p-type impurity of the p⁺-type contact layer 14 of the IGBT region 10.

In the present preferred embodiment, the p⁺-type contact layer 24 is formed simultaneously with the p⁺-type contact layer 14. Therefore, the p⁺-type contact layer 24 is located in a surface portion of a semiconductor layer and has the same impurity concentration profile as the p⁺-type contact layer 14.

The p-type anode layer 25 and the p⁺-type contact layer 24 constitute the first main surface of the semiconductor substrate. Note that the p⁺-type contact layer 24 is a region having higher concentration of a p-type impurity than the p-type anode layer 25, and in a case where it is necessary to distinguish the p⁺-type contact layer 24 and the p-type anode layer 25 from each other, they may be referred to individually, and the p⁺-type contact layer 24 and the p-type anode layer 25 may be collectively referred to as a p-type anode layer.

In the diode region 20, the n⁺-type cathode layer 26 is provided on the second main surface side of the n-type buffer layer 3. The n⁺-type cathode layer 26 is provided between the n⁻-type drift layer 1 and the second main surface. The n⁺-type cathode layer 26 is a semiconductor layer containing, for example, arsenic or phosphorus as an n-type impurity, and concentration of an n-type impurity is 1.0E+16/cm³ to 1.0E+21/cm³. The n⁺-type cathode layer 26 is provided in a part or all of the diode region 20. The n⁺-type cathode layer 26 constitutes the second main surface of the semiconductor substrate.

In FIG. 9, the p-type collector layer 16 provided on the second main surface side of the IGBT region 10 is provided so as to protrude by a distance U1 toward the diode region 20 from a boundary between the IGBT region 10 and the diode region 20. As described above, since the p-type collector layer 16 is provided so as to protrude from the diode region 20, a distance between the n⁺-type cathode layer 26 of the diode region 20 and the active trench gate 11 can be increased, and even in a case where gate drive voltage is applied to the gate trench electrode 11a during freewheeling diode operation, current can be prevented from flowing from a channel formed adjacent to the active trench gate 11 of the IGBT region 10 to the n⁺-type cathode layer 26. The distance U1 may be, for example, 100 μm. Note that the distance U1 may be zero or a distance smaller than 100 μm depending on the application of a semiconductor device 100 which is an RC-IGBT or a semiconductor device 101.

Further, although not illustrated, a p-type impurity may be further selectively implanted into a region where the n⁺-type cathode layer 26 is formed, and a p-type cathode layer may be provided using a part of a region where the n⁺-type cathode layer 26 is formed as a p-type semiconductor.

The diode trench gate 21 penetrates the p-type anode layer 25 and the n-type carrier stored layer 2 from the first main surface of the semiconductor substrate and reaches the n⁻-type drift layer 1. The diode trench electrode 21a faces the p-type anode layer 25, the n-type carrier stored layer 2, and the n⁻-type drift layer 1 via the diode trench insulating film 21b.

The barrier metal 5 is provided on the diode trench electrode 21a and the p⁺-type contact layer 24. The barrier metal 5 is in ohmic contact with the diode trench electrode 21a and the p⁺-type contact layer 24, and is electrically connected to the diode trench electrode and the p⁺-type contact layer 24. The barrier metal 5 may have the same configuration as the barrier metal 5 in the IGBT region 10. The emitter electrode 6 is provided on the barrier metal 5. The emitter electrode 6 provided in the diode region 20 is formed continuously with the emitter electrode 6 provided in the IGBT region 10. Note that, as in the case of the IGBT region 10, the diode trench electrode 21a and the p⁺-type contact layer 24 may be brought into ohmic contact with the emitter electrode 6 without provision of the barrier metal 5. Note that although FIG. 9 illustrates a diagram in which the interlayer insulating film 4 is not provided on the diode trench electrode 21a of the diode trench gate 21, the interlayer insulating film 4 may be formed on the diode trench electrode 21a of the diode trench gate 21. In a case where the interlayer insulating film 4 is formed on the diode trench electrode 21a of the diode trench gate 21, the emitter electrode 6 and the diode trench electrode 21a may be electrically connected in another cross section.

The collector electrode 7 is provided on the second main surface side of the n⁺-type cathode layer 26. Similarly to the emitter electrode 6, the collector electrode 7 of the diode region 20 is formed continuously with the collector electrode 7 provided in the IGBT region 10. The collector electrode 7 is in ohmic contact with the n⁺-type cathode layer 26 and is electrically connected to the n⁺-type cathode layer 26.

In addition to the above configuration, the semiconductor device according to the seventh preferred embodiment has a configuration in which the p-type CSC layer 50 also extends to the diode region 20. In a configuration of the IGBT region 10, as in the third preferred embodiment, a region containing a fourth impurity in the p-type CSC layer 50 reaches below a region containing a third impurity in the n-type carrier stored layer 2. For this reason, also in the diode region 20, a region containing a fourth impurity of the p-type CSC layer 50 reaches below a region containing a third impurity of the n-type carrier stored layer 2.

According to the semiconductor device of the seventh preferred embodiment, in addition to an effect of the third preferred embodiment, an effect that anode implantation efficiency in the diode region 20 can be adjusted by the p-type CSC layer 50 extending in the diode region 20 can be obtained.

### Eighth Preferred Embodiment

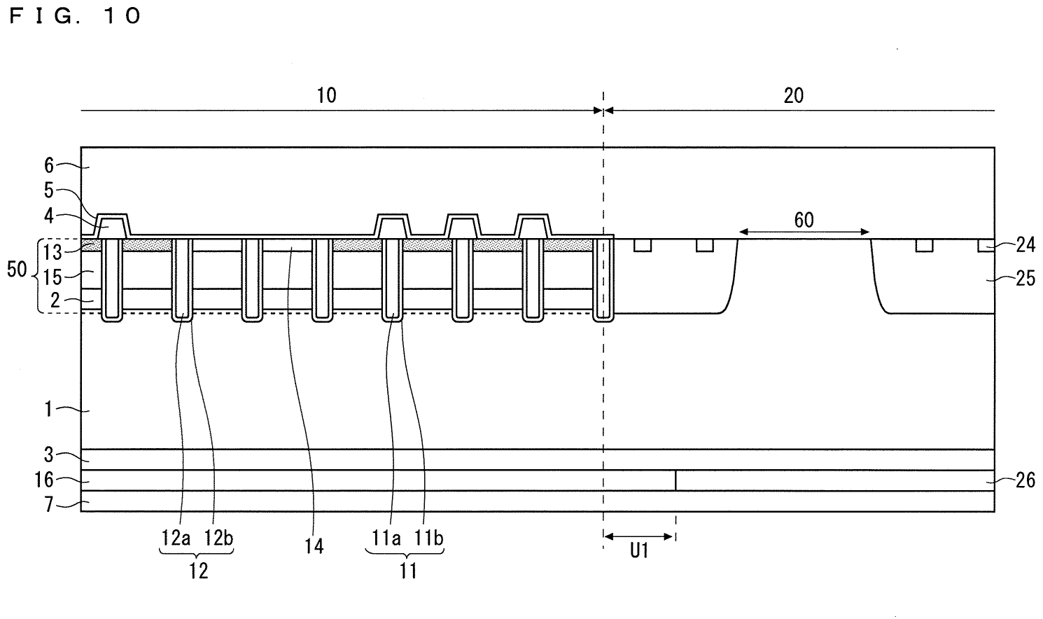

FIG. 10 is a diagram illustrating a configuration of the semiconductor device according to an eighth preferred embodiment, and is a cross-sectional view of the IGBT region 10 and the diode region 20 of an RC-IGBT. A configuration of the IGBT region 10 of the semiconductor device according to the eighth preferred embodiment is also similar to that of the third preferred embodiment.

In the semiconductor device according to the eighth preferred embodiment, the p-type anode layer 25 of the diode region 20 is formed simultaneously with the p-type CSC layer 50. That is, the p-type anode layer 25 is formed by ion-implanting a fourth impurity into the semiconductor substrate and then diffusing the fourth impurity by heat treatment. Therefore, the p-type anode layer 25 is located in a surface portion of a semiconductor layer, and has the same concentration profile of a second impurity as that of the p-type CSC layer 50.

Further, the diode region 20 of the semiconductor device according to the eighth preferred embodiment includes a Schottky region 60 in which the emitter electrode 6 is Schottky connected to the n⁻-type drift layer 1, in addition to a region in which the p-type anode layer 25 is formed in a surface portion of a semiconductor layer. That is, the diode region 20 functions as an MPS diode having a merged PiN Schottky (MPS) structure including a PN junction diode and a Schottky barrier diode. Hereinafter, an RC-IGBT in which the diode region 20 functions as an MPS diode is referred to as an “MPS-RC-IGBT”.

According to the semiconductor device according to the eighth preferred embodiment, the p-type CSC layer 50 can be formed simultaneously with the p-type anode layer 25 of the diode region 20. Therefore, it is not necessary to increase the number of manufacturing processes in order to add the p-type CSC layer 50 to the IGBT region 10.

### Ninth Preferred Embodiment

FIG. 10 is a diagram illustrating a configuration of the semiconductor device according to a ninth preferred embodiment, and is a cross-sectional view of the IGBT region 10 and the diode region 20 of an RC-IGBT. A configuration of the IGBT region 10 of the semiconductor device according to the ninth preferred embodiment is also similar to that of the third preferred embodiment. Further, the diode region 20 includes the Schottky region 60 similarly to the eighth preferred embodiment, and functions as an MPS diode.

In the semiconductor device according to the ninth preferred embodiment, the diode region 20 includes a Schottky adjustment layer 61 having locally different n-type impurity concentration in a surface portion of the n⁻-type drift layer 1 in the Schottky region 60. Further, the p-type CSC layer 50 also extends to the Schottky region 60.

According to the semiconductor device of the ninth preferred embodiment, characteristic adjustment of the Schottky region 60 of an MPS-RC-IGBT can be performed.

Note that, preferred embodiments can be freely combined with each other, and each preferred embodiment can be appropriately modified or omitted.

### Appendix

Hereinafter, various aspects of the present disclosure will be collectively described as an appendix.

### Appendix 1

A semiconductor device comprising:

a source layer of a first conductivity type located in a surface portion of a semiconductor layer and defined by a concentration profile of a first impurity;

a base layer of a second conductivity type located on a lower side of the source layer and defined by a concentration profile of a second impurity;

a carrier stored layer of the first conductivity type located on a lower side of the base layer and defined by a concentration profile of a third impurity;

a drift layer of the first conductivity type located on a lower side of the carrier stored layer; and

a CSC layer of the second conductivity type defined by a concentration profile of a fourth impurity and located such that a region containing the fourth impurity includes a region in which a region containing the second impurity of the base layer and a region containing the third impurity of the carrier stored layer overlap each other.

### Appendix 2

The semiconductor device according to Appendix 1, wherein

concentration of the fourth impurity in the CSC layer is higher than concentration of the second impurity and concentration of the third impurity in the region where the region containing the second impurity of the base layer and the region containing the third impurity of the carrier stored layer overlap each other.

### Appendix 3

The semiconductor device according to Appendix 1 or 2, wherein

the region containing the fourth impurity of the CSC layer includes a region in which a region containing the first impurity of the source layer and the region containing the second impurity of the base layer overlap each other.

### Appendix 4

The semiconductor device according to any one of Appendices 1 to 3, wherein

the region containing the fourth impurity of the CSC layer reaches below the region containing the third impurity of the carrier stored layer.

### Appendix 5

The semiconductor device according to any one of Appendices 1 to 3, wherein

a position of a concentration peak of the fourth impurity in the CSC layer is located below a position of a concentration peak of the third impurity in the carrier stored layer.

### Appendix 6

The semiconductor device according to Appendix 5, wherein

a tail portion in the concentration profile of the fourth impurity of the CSC layer reaches below the region containing the third impurity of the carrier stored layer.

### Appendix 7

The semiconductor device according to Appendix 5 or 6, wherein

the position of the concentration peak of the fourth impurity in the CSC layer is located below the region containing the third impurity of the carrier stored layer.

### Appendix 8

The semiconductor device according to Appendix 4, wherein

the semiconductor layer further includes a diode region functioning as a diode,

the diode region includes an anode layer of the second conductivity type located in the surface portion of the semiconductor layer and having a same concentration profile of the second impurity as that of the base layer, and

the carrier stored layer, the drift layer, and the CSC layer also extend to the diode region.

### Appendix 9

The semiconductor device according to Appendix 4, wherein

the semiconductor layer further includes a diode region functioning as a diode,

the drift layer also extends to the diode region, and

the diode region includes:
a region which is located in the surface portion of the semiconductor layer and in which an anode layer of the second conductivity type having a same concentration profile of the fourth impurity as that of the CSC layer is formed; and
a Schottky region in which an electrode provided on the semiconductor layer is Schottky connected to the drift layer.

### Appendix 10

The semiconductor device according to Appendix 4, wherein

the semiconductor layer further includes a diode region functioning as a diode,

the drift layer also extends to the diode region,

the diode region includes:
a region in which an anode layer of the second conductivity type is formed in the surface portion of the semiconductor layer; and
a Schottky region in which an electrode provided on the semiconductor layer is Schottky connected to the drift layer, and

the CSC layer also extends to the Schottky region.

### Appendix 11

A method of manufacturing a semiconductor device, the method comprising:

(a) a step of forming a CSC layer of a second conductivity type in a semiconductor layer by ion-implanting a fourth impurity into the semiconductor layer and diffusing the fourth impurity by heat treatment;

(b) a step of forming a source layer of a first conductivity type in a surface portion of the semiconductor layer by ion-implanting a first impurity into the semiconductor layer;

(c) a step of forming a base layer of the second conductivity type located on a lower side of the source layer by ion-implanting a second impurity into the semiconductor layer; and

(d) a step of forming a carrier stored layer of the first conductivity type located on a lower side of the base layer by ion-implanting a third impurity into the semiconductor layer, wherein

the steps (b), (c), and (d) are performed after the step (a), and

in the steps (b), (c), and (d), the source layer, the base layer, and the carrier stored layer are formed such that a junction portion between the source layer and the base layer and a junction portion between the base layer and the carrier stored layer are included in the CSC layer formed in the step (a).

While the disclosure has been shown and described in detail, the foregoing description is in all aspects illustrative and not restrictive. It is therefore understood that numerous modifications and variations can be devised.

What is claimed is:

1. A semiconductor device comprising:
a source layer of a first conductivity type located in a surface portion of a semiconductor layer and defined by a concentration profile of a first impurity;
a base layer of a second conductivity type located on a lower side of the source layer and defined by a concentration profile of a second impurity;
a carrier stored layer of the first conductivity type located on a lower side of the base layer and defined by a concentration profile of a third impurity;
a drift layer of the first conductivity type located on a lower side of the carrier stored layer; and
a CSC layer of the second conductivity type defined by a concentration profile of a fourth impurity and located such that a region containing the fourth impurity includes a region in which a region containing the second impurity of the base layer and a region containing the third impurity of the carrier stored layer overlap each other.

2. The semiconductor device according to claim 1, wherein
concentration of the fourth impurity in the CSC layer is higher than concentration of the second impurity and concentration of the third impurity in the region where the region containing the second impurity of the base layer and the region containing the third impurity of the carrier stored layer overlap each other.

3. The semiconductor device according to claim 1, wherein
the region containing the fourth impurity of the CSC layer includes a region in which a region containing the first impurity of the source layer and the region containing the second impurity of the base layer overlap each other.

4. The semiconductor device according to claim 1, wherein
the region containing the fourth impurity of the CSC layer reaches below the region containing the third impurity of the carrier stored layer.

5. The semiconductor device according to claim 1, wherein
a position of a concentration peak of the fourth impurity in the CSC layer is located below a position of a concentration peak of the third impurity in the carrier stored layer.

6. The semiconductor device according to claim 5, wherein
a tail portion in the concentration profile of the fourth impurity of the CSC layer reaches below the region containing the third impurity of the carrier stored layer.

7. The semiconductor device according to claim 5, wherein
the position of the concentration peak of the fourth impurity in the CSC layer is located below the region containing the third impurity of the carrier stored layer.

8. The semiconductor device according to claim 4, wherein
the semiconductor layer further includes a diode region functioning as a diode,
the diode region includes an anode layer of the second conductivity type located in the surface portion of the semiconductor layer and having a same concentration profile of the second impurity as that of the base layer, and
the carrier stored layer, the drift layer, and the CSC layer also extend to the diode region.

9. The semiconductor device according to claim 4, wherein
the semiconductor layer further includes a diode region functioning as a diode,
the drift layer also extends to the diode region, and
the diode region includes:
a region which is located in the surface portion of the semiconductor layer and in which an anode layer of the second conductivity type having a same concentration profile of the fourth impurity as that of the CSC layer is formed; and
a Schottky region in which an electrode provided on the semiconductor layer is Schottky connected to the drift layer.

10. The semiconductor device according to claim 4, wherein
the semiconductor layer further includes a diode region functioning as a diode,
the drift layer also extends to the diode region,
the diode region includes:
a region in which an anode layer of the second conductivity type is formed in the surface portion of the semiconductor layer; and
a Schottky region in which an electrode provided on the semiconductor layer is Schottky connected to the drift layer, and
the CSC layer also extends to the Schottky region.

11. A method of manufacturing a semiconductor device, the method comprising:
(a) a step of forming a CSC layer of a second conductivity type in a semiconductor layer by ion-implanting a fourth impurity into the semiconductor layer and diffusing the fourth impurity by heat treatment;
(b) a step of forming a source layer of a first conductivity type in a surface portion of the semiconductor layer by ion-implanting a first impurity into the semiconductor layer;
(c) a step of forming a base layer of the second conductivity type located on a lower side of the source layer by ion-implanting a second impurity into the semiconductor layer; and
(d) a step of forming a carrier stored layer of the first conductivity type located on a lower side of the base layer by ion-implanting a third impurity into the semiconductor layer, wherein
the steps (b), (c), and (d) are performed after the step (a), and
in the steps (b), (c), and (d), the source layer, the base layer, and the carrier stored layer are formed such that a junction portion between the source layer and the base layer and a junction portion between the base layer and the carrier stored layer are included in the CSC layer formed in the step (a).
